(19) United States
(12) Patent Application Publication
(10) Pub. No.: US 2015/0114603 A1
(43) Pub. Date: Apr. 30, 2015

(54) HEAT PIPE WITH ULTRA-THIN CAPILLARY STRUCTURE

(71) Applicant: Hao PAI, New Taipei City (TW)

(72) Inventor: Hao PAI, New Taipei City (TW)

(21) Appl. No.: 14/145,573

(22) Filed: Dec. 31, 2013

(30) Foreign Application Priority Data
Oct. 29, 2013 (TW) 102139180

(51) Int. Cl. F28D 15/04; H05K 7/20

(52) U.S. Cl. CPC F28D 15/04; H05K 7/20336
USPC 165/104.26

(57) ABSTRACT

A heat pipe with an ultra-thin capillary structure includes a tube body being hollow and flat, and a capillary structure disposed in the tube body and shaped as a thin plate. The capillary structure has a first adhering surface attaching on a partial portion of an inner wall of the tube body, a forming surface opposite to the first adhering surface, and a second adhering surface forming at one side between the first adhering surface and the forming surface. The second adhering surface is attached on the inner wall so that a vapor channel is formed between the forming surface and the inner wall; wherein the forming surface elongates along a longitudinal direction of the vapor channel, and is tapered to form an inclined interface between the capillary structure and the vapor channel as a capillary transmission surface.

### BACKGROUND OF THE INVENTION

1. Field of the Invention

The present invention generally relates to a miniaturized heat pipe, more particularly to a heat pipe with an ultra-thin capillary structure.

2. Description of the Related Art

Nowadays, electronic products are tending to small volumes in order to be easily carried. Since the volumes are smaller, some kinds of electronic products that need to dissipate heat inside should focus on the issue of the volume of a heat pipe. In order to minimize the heat pipe in the electronic products, an ultra-thin heat pipe, which has thickness under 1.5 mm, is then developed.

However, a capillary structure inside the ultra-thin heat pipe shall follow the design tendency to be smaller as well. To design the capillary structure, it may focus on the inner space of a heat pipe in order to avoid that the inner space is too small to let air or a fluid be through. That is, when an ultra-thin heat pipe is manufactured in a sintering process, its volume is designed very small to cause that metal powders are not able to be through a gap between a mandrel bar and the inner wall of the ultra-thin heat pipe, and part of the metal powders may not be positioned in the ultra-thin heat pipe. That is why a powdered capillary structure of an ultra-thin heat pipe is only formed at a location of the heat pipe without completion in prior arts. As a conclusion, a sectional surface of an ultra-thin heat pipe is hardly filled with the powdered capillary structure in prior arts. As it can be seen, this kind of powdered capillary structure may be short of a better vaporization surface area, a better condensation surface area, a better liquid transmission sectional surface area, a fluent vapor channel, and a reinforced supporting structure, and we would know the prior ultra-thin heat pipe should be improved in the aspect of heat transmission.

Accordingly, how to improve the heat transmission of an ultra-thin heat pipe in prior arts is an important issue to the people skilled in the art.

### SUMMARY OF THE INVENTION

In one aspect, the present invention is to provide a heat pipe with an ultra-thin capillary structure. It is to form a miniaturized capillary structure on an inner wall of a heat pipe in order to maintain an enough space of a vapor channel for heat exchange, for example vaporization and condensation. Furthermore, the heat pipe has a largest capillary surface area and a capillary transmission area, so as to approach the aspect with a miniaturized heat pipe.

In order to perform the above aspect, a heat pipe with an ultra-thin capillary structure provided by the present invention comprises: a tube body, which is hollow and flat; and a capillary structure, which is in the tube body and is shaped as a thin plate; the capillary structure has a first adhering surface attached on a partial portion of an inner wall of the tube body, a forming surface opposite to the first adhering surface, and a second adhering surface formed at one side between the first adhering surface and the forming surface The second adhering surface is attached on the inner wall of the tube body, so that a vapor channel is formed between the forming surface and the inner wall of the tube body; wherein the forming surface elongates along a longitudinal direction of the vapor channel and is tapered to form an inclined interface between the capillary structure and the vapor channel as a capillary transmission surface.

### BRIEF DESCRIPTION OF THE DRAWINGS

The objects, spirits, and advantages of the preferred embodiments of the present invention will be readily understood by the accompanying drawings and detailed descriptions, wherein:

FIG. 1 illustrates a schematic perspective view of a first embodiment according to the present invention;

FIG. 2 illustrates a schematic cross-sectional view from a line 2-2 of FIG. 1 according to the present invention;

FIG. 3 illustrates a schematic cross-sectional view of a second embodiment according to the present invention;

FIG. 4 illustrates a schematic cross-sectional view from a line 4-4 of FIG. 3 according to the present invention;

FIG. 5 illustrates a schematic perspective view of a third embodiment according to the present invention;

FIG. 6 illustrates a schematic perspective view of a fourth embodiment according to the present invention;

FIG. 7 illustrates a schematic perspective view of a fifth embodiment according to the present invention;

FIG. 8 illustrates a schematic cross-sectional view from a line 8-8 of FIG. 7 according to the present invention;

FIG. 9 illustrates a schematic perspective view of a sixth embodiment according to the present invention; and

FIG. 10 illustrates a schematic partial sectional view from inside a tube body of the sixth embodiment according to the present invention; and

FIG. 11 illustrates a partially enlarged view of an A portion of FIG. 10.

### DETAILED DESCRIPTION OF THE INVENTION

Following preferred embodiments and figures will be described in detail so as to achieve aforesaid objects.

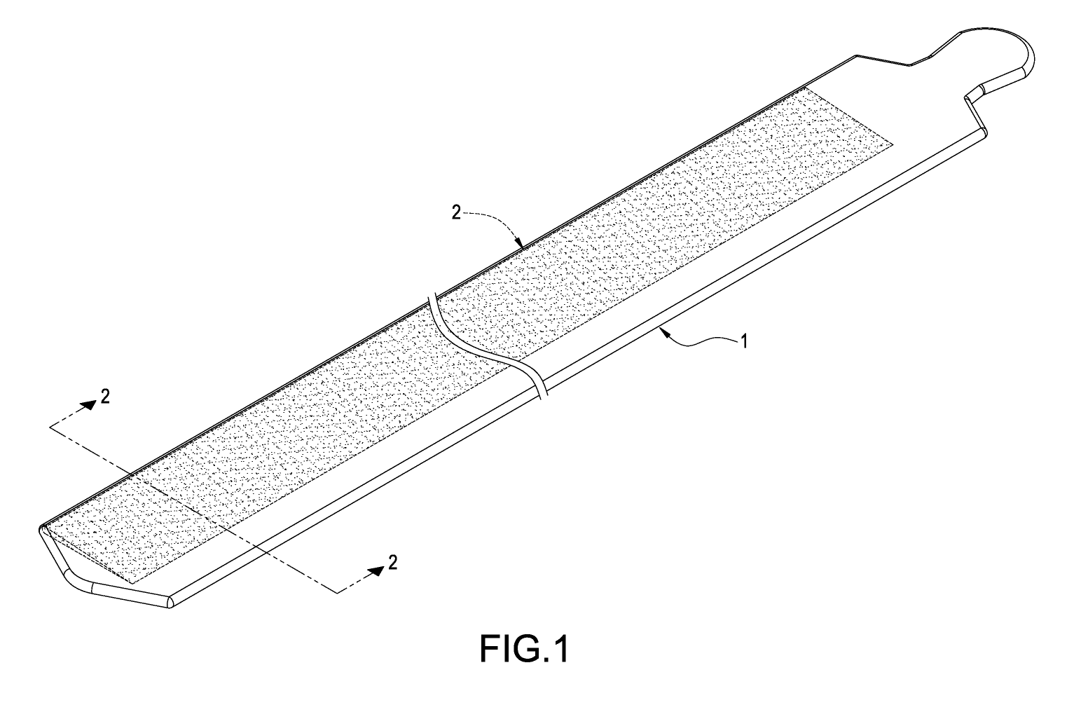

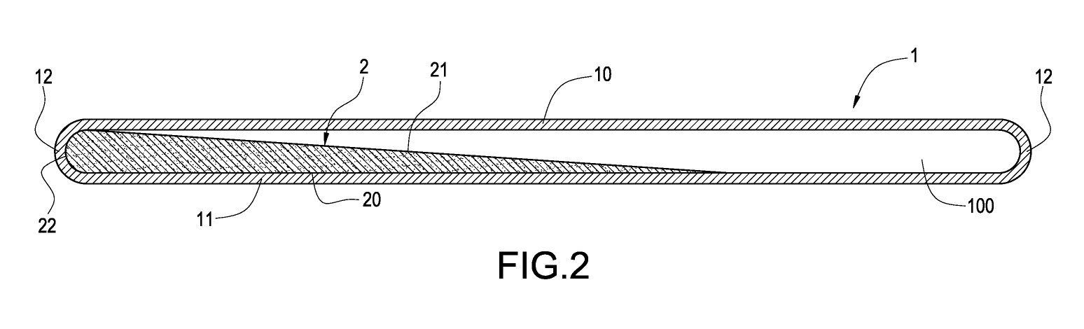

Please refer to FIG. 1 and FIG. 2, which illustrate a schematic perspective view of the present invention and a schematic cross-sectional view from a line 2-2 of FIG. 1 according to the present invention. The present invention provides a heat pipe with an ultra-thin capillary structure. The heat pipe comprises a tube body 1 that is hollow and flat, and at least one capillary structure 2 that is in the tube body 1 and contacts with a partial inner wall of the tube body 1. The tube body 1 is formed by a pressing process, and is a flat type with a thickness under 0.5 mm. When the tube body 1 is formed, the tube body 1 comprises an upper wall 10, a lower wall 11, and a plurality of side edges 12, wherein the upper wall 10 and the lower wall 11 are arranged corresponding to each other, and the side edges 12 are at the peripherals between the upper wall 10 and the lower wall 11.

As shown in FIG. 2, the capillary structure 2 is disposed in the tube body 1. The capillary structure 2 is made by knit, fiber, sintered metal powders, or any of their combination, in order to form a shape of thin plate. Prior to dispose the capillary structure 2 in the tube body 1, the capillary structure 2 is made. As a matter of fact, the capillary structure 2 is placed in the tube body and simultaneously pressed with the tube body 1 so as to be located at an side in the tube body 1. The capillary structure 2 has a first adhering surface 20 that is attached on a partial portion of an inner wall of the tube body 1, a forming surface 21 that is continuously tapered and opposite to the first adhering surface 20, and a second adhering surface 22 formed at one side between the first adhering surface 20 and the forming surface 21. As aforesaid, the wick structure 2 is positioned in the tube by attaching the first adhering surface 20 on the partial portion of the inner wall of the tube body 1, and after the wick structure as well as the tube body 1 is pressed, the second adhering surface 22 of the capillary structure 2 will be attached to the inner wall of the tube body 1. Continuously, a vapor channel 100 is formed between the forming surface 21 and the inner wall of the tube body 1. In particular, because of the pressing, the first adhering surface 20 and the second adhering surface 22 elongate along a longitudinal direction of the vapor channel 100, which is the same as the longitudinal direction of the tube body 1 as in this embodiment, and a porosity of the forming surface 21 is gradually lowered along a direction away from the second adhering surface 22. Factor to make this porosity feature of the forming surface 21 is that the capillary structure 2 is pre-made and extruded when pressing the tube body 1.

The forming surface 21 also elongates along the longitudinal direction of the vapor channel 100 and is tapered, so the forming surface 210 forms an inclined interface between the capillary structure 2 and the vapor channel 100, which increases a surface area between the capillary structure 2 and the vapor channel 100, so as to reduce flow resistance of vapor flow in the vapor channel 100, and increase a capillary surface area of working fluid flowing back to the capillary structure 2, in order to achieve a better heat-exchange effect as the heat pipe 1 is miniaturized.

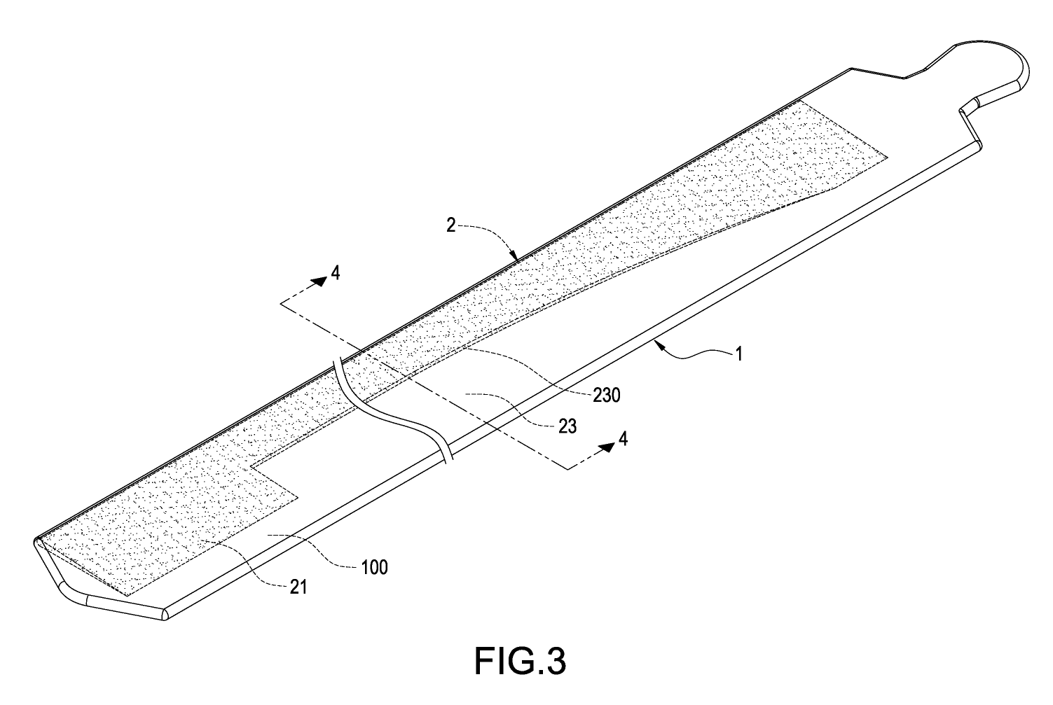

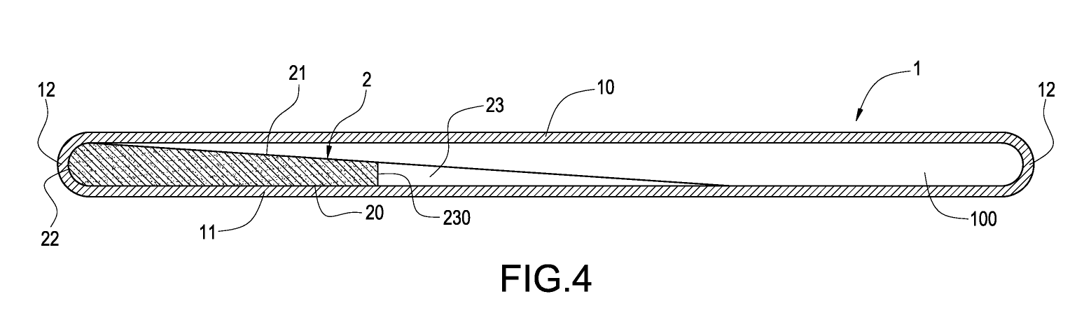

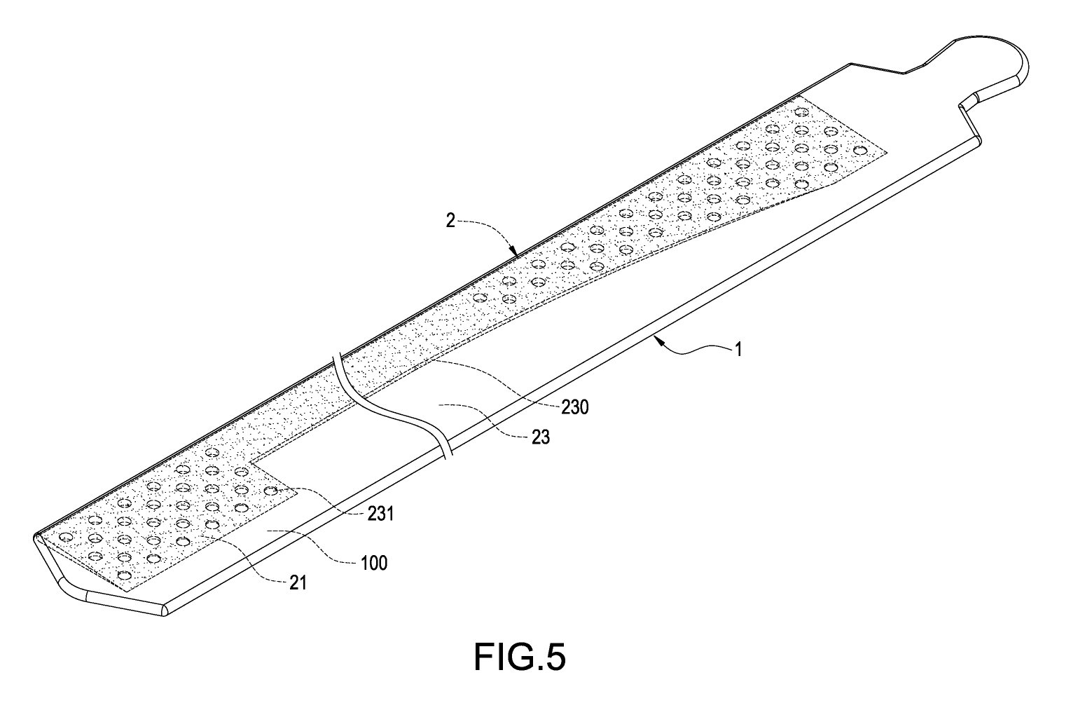

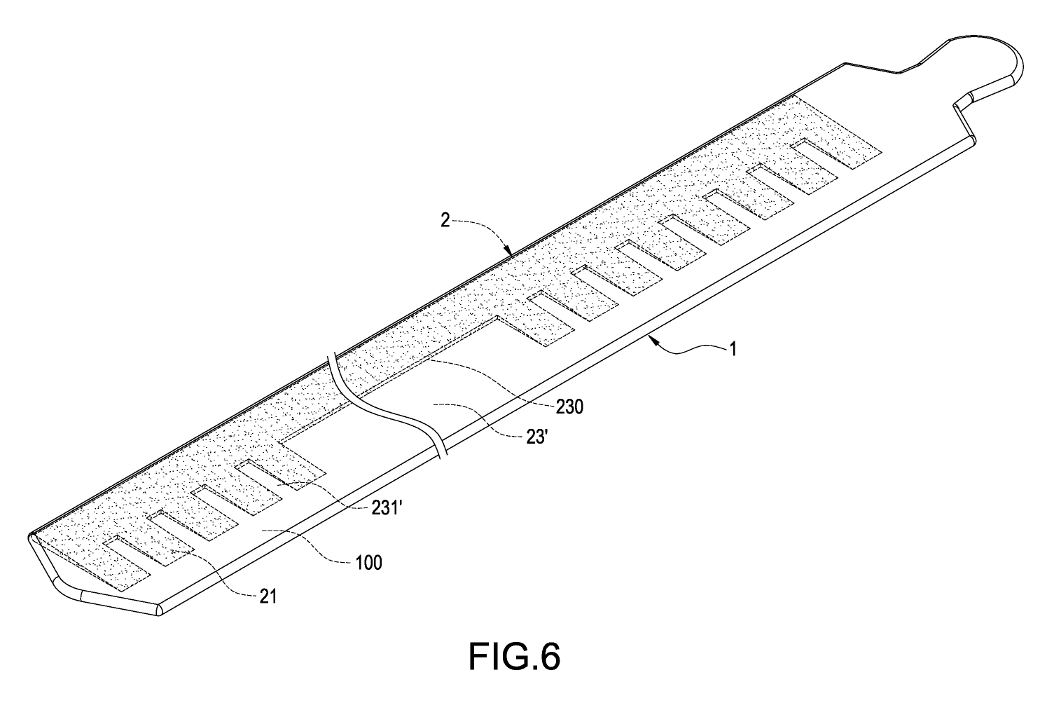

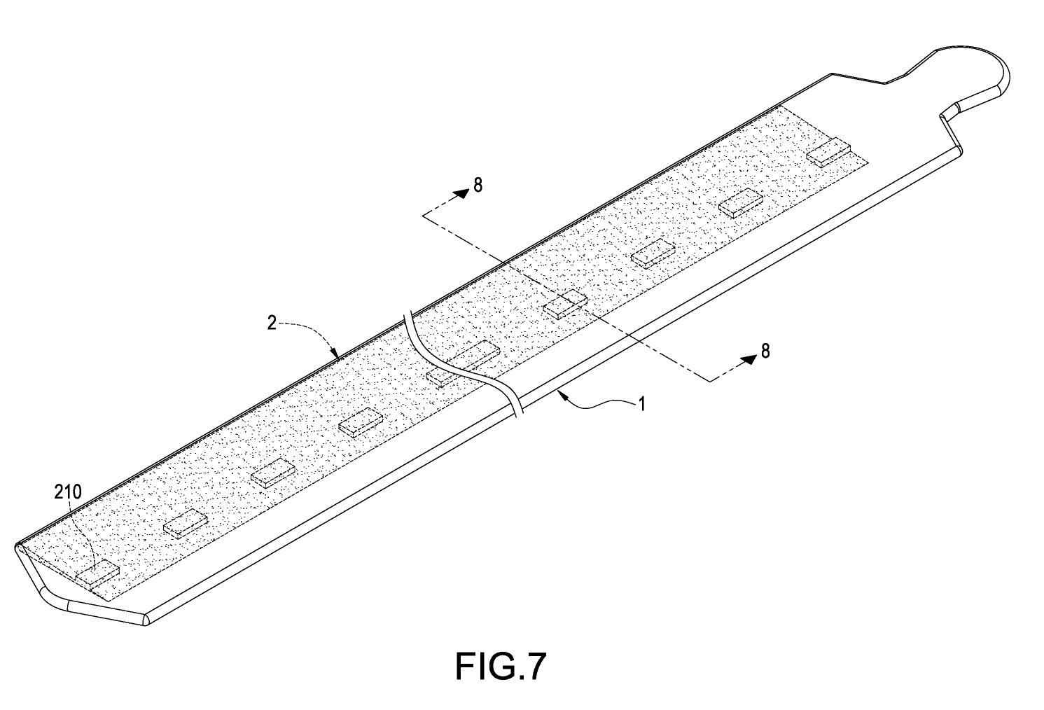

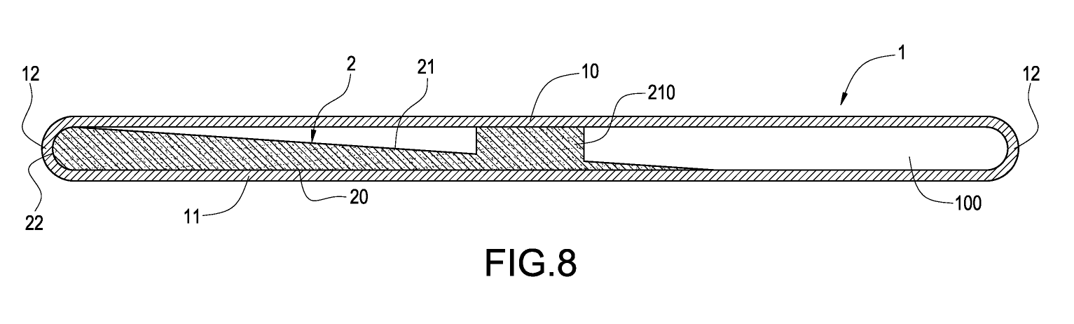

As shown in FIG. 3 and FIG. 4, the capillary structure 2 includes a bare area 23. In particular, the bare area 23 is a cut-out formed at a location substantially between a vaporizing section and a condensation section of a heat pipe, that is, at a transmission section of a heat pipe. Preferably, a cutting edge 230 is formed to make the capillary structure 2 in the transmission section along the longitudinal direction of the vapor channel 100 between the vaporizing section and the condensation section be tapered. As shown in FIG. 5, the forming surface 21 further has a plurality of air flow holes 231 that passes through the capillary structure 2 to expose the inner wall of the tube body 1, in order to increase a capillary transmission area. As shown in FIG. 6, in addition to a cut-out 23′ formed in the transmission section, there are a plurality of smaller cut-outs 231′ formed in the vaporizing section and the condensation section. As shown in FIG. 7 and FIG. 8, a plurality of support portions 210 are formed on the forming surface 21 of the capillary structure 2 to be part of the capillary structure 2, and each of the support portions 210 is protruded upwardly to abut the inner wall of the tube body 1 for supporting the tube body 1. In particular, the support portions 210 are arranged by interval or are continuously arranged along the longitudinal direction of the vapor channel 100.

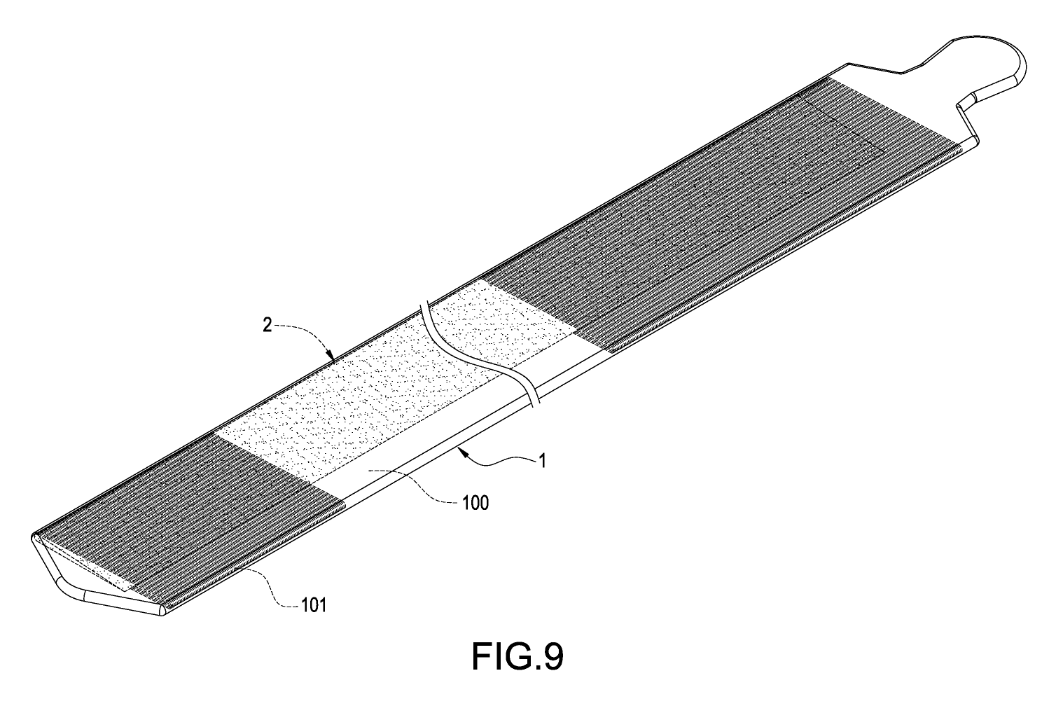

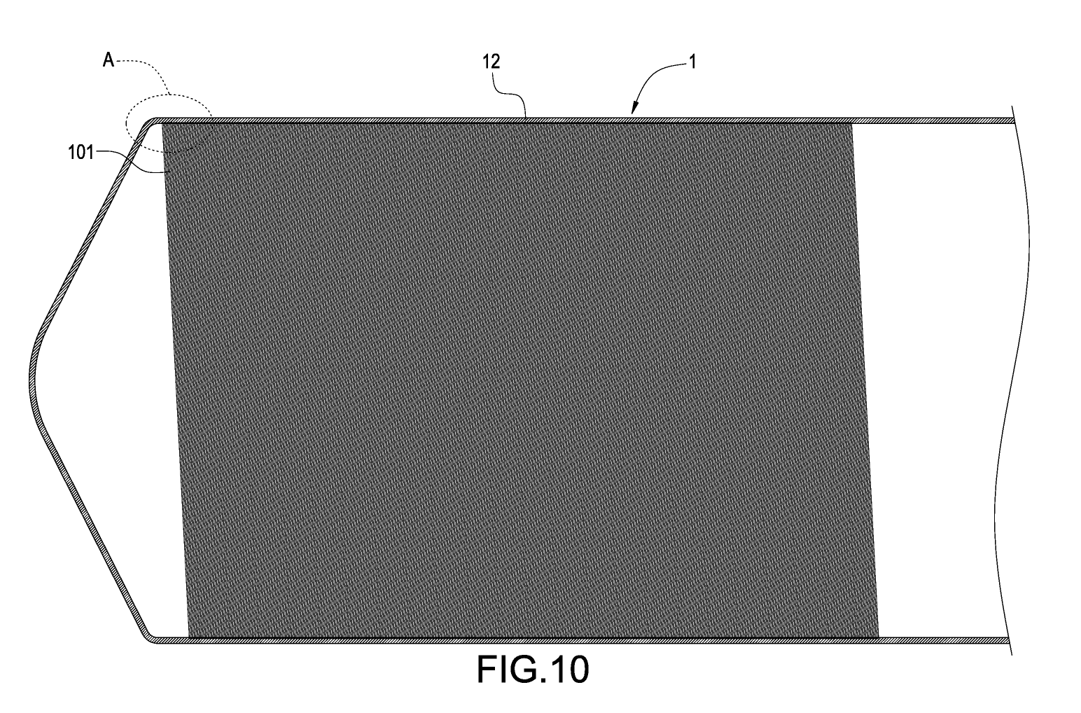

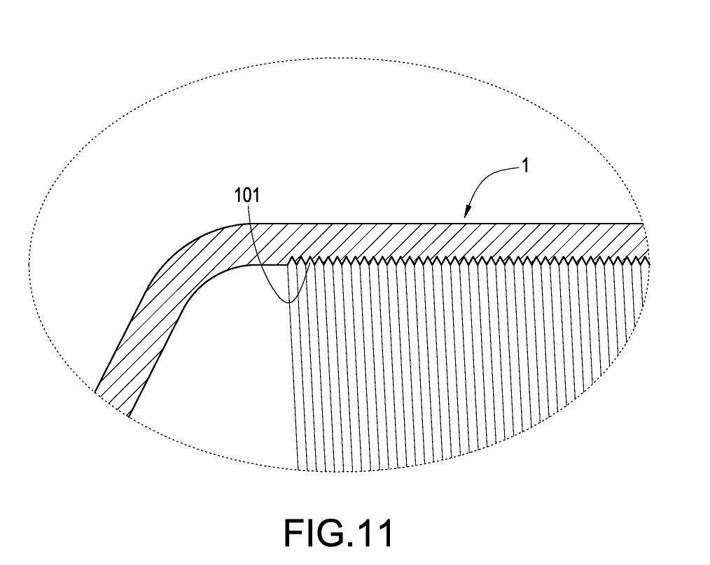

As shown in FIG. 9 and FIG. 10, there are a plurality of grooves 101 that are radially threaded, in right helical direction, left helical direction, or both, or even irregularly, on the inner wall of the tube body 1. A depth of the groove 101 is less than 0.03 mm, as shown in FIG. 11, and is usually less than 30% of a thickness of the tube body 1 as well. As it can be seen, since the grooves 101 are formed on the inner surface of the tube body 1, the structure of the grooves 101 will not interfere the formation of the vapor channel 100. Meanwhile, the grooves 101 are radially threaded to surround on the inner wall of the tube body 1, the liquid working fluid can flow back radially to the capillary structure 2; on the other hand, the liquid working fluid (longitudinally) flowing back axially is through the capillary structure 2 as well. Therefore, the grooves 101 can provide auxiliary help to the capillary structure 2 help to form a capillary transmission net that covers totally the inner wall of the tube body 1.

Accordingly, by means of above described structure, a heat pipe with an ultra-thin capillary structure is achieved.

Although the invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A heat pipe with an ultra-thin capillary structure, comprising:
a tube body (1), being hollow and flat; and
a capillary structure (2), being in the tube body (1) and being shaped as a thin plate, having a first adhering surface (20) attaching on a partial portion of an inner wall of the tube body (1), a forming surface (21) corresponding to the first adhering surface (20), and a second adhering surface (22) formed at one side between the first adhering surface (20) and the forming surface (21), the second adhering surface (22) being attached on the inner wall of the tube body (1), and a vapor channel (100) being formed between the forming surface (21) and the inner wall of the tube body (1);
wherein the forming surface (21) elongates along a longitudinal direction of the vapor channel (100)and is tapered to form an inclined interface between the capillary structure (2) and the vapor channel (100) as a capillary transmission surface.

2. The heat pipe with an ultra-thin capillary structure according to claim 1, wherein a thickness of the flat tube body (1) is under 0.5 mm.

3. The heat pipe with an ultra-thin capillary structure according to claim 1, wherein the capillary structure (2) is made by selecting a group consisting of knit, fiber and sintered metal powders and their combination.

4. The heat pipe with an ultra-thin capillary structure according to claim 1, wherein the capillary structure (2) has a bare area (23) formed on the forming surface (21).

5. The heat pipe with an ultra-thin capillary structure according to claim 4, wherein a cutting edge (230) is formed to make the capillary structure (2) in a transmission section along the longitudinal direction of the vapor channel (100) between a vaporizing section and a condensation section be tapered.

6. The heat pipe with an ultra-thin capillary structure according to claim 1, wherein a porosity of the forming surface (21) is gradually lowered along a direction away from the second adhering surface (22).

7. The heat pipe with an ultra-thin capillary structure according to claim 1, wherein the forming surface (21) has a plurality of air flow holes (231) that passes through the capillary structure (2) to expose the inner wall of the tube body (1).

8. The heat pipe with an ultra-thin capillary structure according to claim 1, wherein a plurality of smaller cut-outs (231′) are formed in a vaporizing section and a condensation section.

9. The heat pipe with an ultra-thin capillary structure according to claim 1, wherein a plurality of support portions (210) are formed on the forming surface (21) of the capillary structure (2), and each of the support portions (210) is protruded upwardly from the forming surface (21) to abut the inner wall of the tube body (1) for supporting the tube body (1).

10. The heat pipe with an ultra-thin capillary structure according to claim 9, wherein the plurality of support portions (210) are arranged by interval or are continuously arranged along the longitudinal direction of the vapor channel (100).

11. The heat pipe with an ultra-thin capillary structure according to claim 1, wherein the capillary structure (2) has a plurality of grooves (101) that are radially threaded on the inner wall of the tube body (1), a depth of the groove (101) being less than 30% of a thickness of of the tube body (1).

12. The heat pipe with an ultra-thin capillary structure according to claim 11, wherein the depth of the groove (101) is less than 0.03 mm.
